(19) United States
(12) Patent Application Publication
(10) Pub. No.: US 2026/0371985 A1
(43) Pub. Date: Nov. 19, 2026

(54) SUBSTRATE TREATING APPARATUS

(71) Applicant: Samsung Electronics Co., Ltd., Suwon-si (KR)

(72) Inventors: Yun Pyo HONG, Suwon-si (KR); Dong Gap SHIN, Suwon-si (KR); Si Woong WOO, Suwon-si (KR); Byeong Kyu LIM, Suwon-si (KR); Sang Ho RHA, Suwon-si (KR); Kyeong Bin LIM, Suwon-si (KR)

(21) Appl. No.: 19/537,681

(22) Filed: Feb. 12, 2026

(30) Foreign Application Priority Data
May 16, 2025 (KR) 10-2025-0063868

(51) Int. Cl. H10P 72/00; B24B 57/02

(52) U.S. Cl. CPC H10P 72/0428; B24B 57/02; H10P 72/0402

(57) ABSTRACT

A substrate treating apparatus includes an electronic pressure regulator and/or a stabilization algorithm for stabilizing the air bearing. The substrate treating apparatus includes a base, a polishing pad configured to polish a substrate on the base, a slurry supply arm which is adjacent to the polishing pad and configured to supply a slurry, and a spindle assembly configured to polish the substrate in conjunction with the polishing pad. The spindle assembly includes a polishing head configured to adsorb the substrate, a spindle rotor which engages with the polishing head and configured to rotate the polishing head, a fluid supply unit configured to supply a fluid, a fluid supply line connects the fluid supply unit and the spindle rotor, and a pressure controller which is installed on the fluid supply line and configured to electrically control the pressure supplied to the spindle rotor.

### CROSS-REFERENCE TO RELATED APPLICATION

This application claims benefit of priority under 35 U.S.C. § 119 to Korean Patent Application No. 10-2025-0063868, filed on May 16, 2025 in the Korean Intellectual Property Office, the disclosure of which is incorporated by reference herein in its entirety.

### TECHNICAL FIELD

The present disclosure relates to a substrate treating apparatus used in a semiconductor fabricating process, and more specifically, to a substrate treating apparatus used in a polishing process.

### BACKGROUND

When fabricating a semiconductor device, a polishing process may be performed to flatten the surface of a substrate. The polishing process may be performed using a chemical mechanical polishing (CMP) apparatus, and the chemical mechanical polishing apparatus may be implemented as a grinding apparatus including a polishing head.

The chemical mechanical polishing apparatus may use an air bearing to enable stable high-speed rotation of the polishing head. However, during substrate processing, the air bearing may lose stability due to various defects such as voids and edge tearing.

### SUMMARY

Aspects of the present disclosure provide a substrate treating apparatus including an electronic pressure regulator and/or a stabilization algorithm for stabilizing the air bearing.

However, aspects of the present disclosure are not limited to the one set forth herein. The above and other aspects of the present disclosure will become more apparent to one of ordinary skill in the art to which the present disclosure pertains by referencing the detailed description of the present disclosure given below.

According to an aspect of the present disclosure, a substrate treating apparatus includes a base, a polishing pad which is provided on the base and configured to polish a substrate, a slurry supply arm which is adjacent to the polishing pad and configured to supply a slurry, and a spindle assembly which is provided on the polishing pad and configured to polish the substrate in conjunction with the polishing pad, wherein the spindle assembly includes a polishing head configured to adsorb the substrate, a spindle rotor which engages with the polishing head and configured to rotate the polishing head, a fluid supply unit configured to supply a fluid, a fluid supply line configured to connect the fluid supply unit and the spindle rotor, and a pressure controller which is installed on the fluid supply line and configured to electrically control the pressure supplied to the spindle rotor.

According to another aspect of the present disclosure, a substrate treating apparatus includes a base, a polishing pad which is provided on the base and configured to polish a substrate, a slurry supply arm which is adjacent to the polishing pad and configured to supply a slurry, and a spindle assembly which is provided on the polishing pad and configured to polish the substrate in conjunction with the polishing pad, wherein the spindle assembly includes a polishing head configured to adsorb the substrate, a spindle rotor which engages with the polishing head and configured to rotate the polishing head, a fluid supply unit configured to supply a fluid, a fluid supply line configured to connect the fluid supply unit and the spindle rotor, and a pressure controller which is installed on the fluid supply line and configured to electrically control the pressure supplied to the spindle rotor, wherein the fluid supply line includes a first supply line configured to be connected to the fluid supply unit, a second supply line configured to connect the first supply line and a first portion of the spindle rotor, a third supply line configured to connect the first supply line and a second portion of the spindle rotor, and a fourth supply line configured to connect the first supply line and a third portion of the spindle rotor, and wherein the third supply line is disposed at a level lower than the second supply line and the fourth supply line, and the pressure controller independently controls the pressure provided through the second portion.

According to another aspect of the present disclosure, a substrate treating apparatus includes a base, a polishing pad which is provided on the base and configured to polish a substrate, a slurry supply arm which is adjacent to the polishing pad and configured to supply a slurry, and a spindle assembly which is provided on the polishing pad and configured to polish the substrate in conjunction with the polishing pad, wherein the spindle assembly includes a polishing head configured to adsorb the substrate, a spindle rotor which engages with the polishing head and configured to rotate the polishing head, a fluid supply unit configured to supply a fluid, a fluid supply line configured to connect the fluid supply unit and the spindle rotor, a pressure controller which is installed on the fluid supply line and configured to electrically control the pressure supplied to the spindle rotor, a flow sensor configured to measure the flow rate in the fluid supply line, and a stabilizer configured to determine the pressure provided to the spindle rotor on the basis of a measured result of the flow sensor, wherein the fluid supply line includes a first supply line configured to be connected to the fluid supply unit, a second supply line configured to connect the first supply line and a first portion of the spindle rotor, a third supply line configured to connect the first supply line and a second portion of the spindle rotor, and a fourth supply line configured to connect the first supply line and a third portion of the spindle rotor, and wherein the third supply line is disposed at a level lower than the second supply line and the fourth supply line, the flow sensor is installed in the third supply line, and the pressure controller independently controls the pressure provided through the second portion.

It should be noted that the effects of the present disclosure are not limited to those described above, and other effects of the present disclosure may be apparent from the following description, and/or may be learned by practice of the presented implementations.

### BRIEF DESCRIPTION OF DRAWINGS

The above and other aspects, features, and advantages of certain implementations of the present disclosure may be more apparent from the following description taken in conjunction with the attached drawings, in which:

FIGS. 1 and 2 are exemplary diagrams illustrating an internal structure of a semiconductor fabricating equipment according to some implementations of the present disclosure.

FIG. 3 is a plan view illustrating an internal structure of the substrate treating apparatus according to some implementations of the present disclosure.

FIG. 4 is a perspective view illustrating the internal structure of the substrate treating apparatus according to some implementations of the present disclosure.

FIGS. 5-12 are exemplary diagrams illustrating the internal structure of a spindle assembly that constitutes the substrate treating apparatus according to some implementations of the present disclosure.

FIGS. 13 and 14 are exemplary diagrams illustrating a stabilizer in a spindle assembly that constitutes a substrate treating apparatus according to some implementations of the present disclosure.

FIGS. 15-19 are exemplary diagrams illustrating an internal structure of a spindle assembly that constitutes the substrate treating apparatus according to some implementations of the present disclosure.

### DETAILED DESCRIPTION

The following description with reference to the accompanying drawings is provided to assist in a comprehensive understanding of implementations of the present disclosure defined by the claims and their equivalents. Various specific details are included to assist in understanding, but these details are considered to be exemplary only. Therefore, those of ordinary skill in the art may recognize that various changes and modifications of the implementations described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used merely to distinguish one component from another, and should not be construed as limiting in any other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it may indicate that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one implementation,” “an implementation,” “an example implementation,” or similar language may indicate that a particular feature, structure, or characteristic described in connection with the indicated implementation is included in at least one implementation of the present solution. Thus, the phrases “in one implementation”, “in an implementation,” “in an example implementation,” and similar language throughout this disclosure may, but do not necessarily, all refer to the same implementation. The implementations described herein are example implementations, and thus, the disclosure is not limited thereto and may be realized in various other forms.

The implementations herein may be described and illustrated in terms of blocks, as shown in the drawings, which carry out a described function or functions. These blocks, which may be referred to herein as units or modules or the like, or by names such as, but not limited to, device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, implementations of the present disclosure are described with reference to the accompanying drawings.

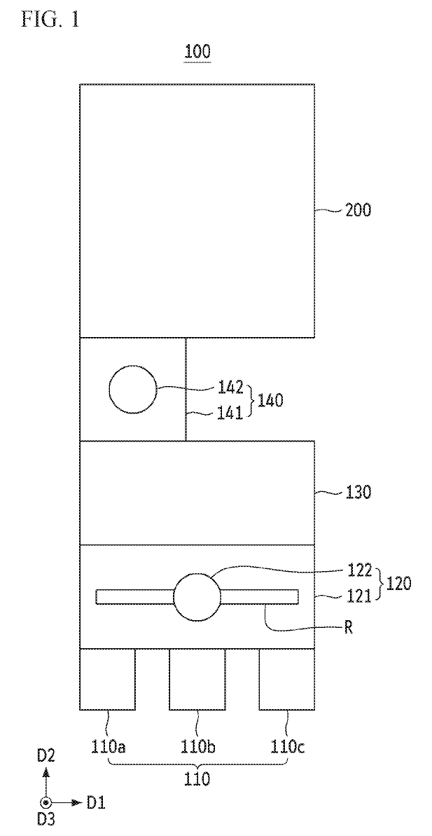

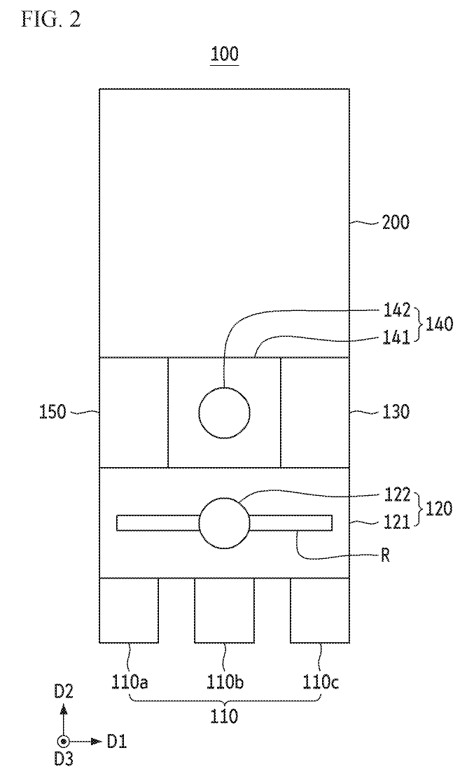

FIG. 1 is a first exemplary diagram illustrating an internal structure of a semiconductor fabricating equipment according to some implementations of the present disclosure. FIG. 2 is a second exemplary diagram illustrating the internal structure of the semiconductor fabricating equipment according to some implementations of the present disclosure. Hereinafter, the semiconductor fabricating equipment 100 including the substrate treating apparatus 200 will be described first, and the substrate treating apparatus 200 will be described later.

The semiconductor fabricating equipment 100 may include the substrate treating apparatus 200 for performing a polishing process. The semiconductor fabricating equipment 100 may include a single substrate treating apparatus 200 but may also include a plurality of substrate treating apparatuses 200, without being limited thereto. Referring to FIGS. 1 and 2, the semiconductor fabricating equipment 100 may be configured to include a load port module 110, an index module 120, a cleaning module 130, a transfer module 140, and the substrate treating apparatus 200.

A first direction D1 and a second direction D2 may constitute a two-dimensional plane. The first direction D1 may be an X-axis direction, and the second direction D2 may be a Y-axis direction. The first direction D1 may be a left-right direction, and the second direction D2 may be a front-back direction. In some implementations, the first direction D1 may be the front-back direction, and the second direction D2 may be the left-right direction. A third direction D3 may form a three-dimensional solid together with the first direction D1 and the second direction D2. The third direction D3 is a direction perpendicular to a plane formed by the first direction D1 and the second direction D2. The third direction D3 may be a Z-axis direction. The third direction D3 may be an up-down direction.

The load port module 110 may provide the container with a seating face. The container may be transported to the load port module 110 by a ceiling transport device or a ground transport device. The container may accommodate a plurality of substrates. For example, the container may be provided as a front opening unified pod (FOUP). The ceiling transport device may transport the container, while moving on the ceiling of the semiconductor fabricating plant. For example, the ceiling transport device may be provided as an overhead hoist transport (OHT). The ground transport device may transport the container, while moving on the ground of the semiconductor fabricating plant. For example, the ground transport device may be provided as an autonomous mobile robot (AMR) or an automatic guided vehicle (AGV).

The load port module 110 may load or unload the container itself. The load port module 110 may load or unload the substrate accommodated in the container. A plurality of load port modules 110 may be provided in front of the index module 120. For example, three load ports 110a, 110b, and 110c, such as a first load port 110a, a second load port 110b,and a third load port 110c, may be disposed in front of the index module 120. The three load ports 110a, 110b, and 110c may be disposed in the first direction D1, but may also be disposed in the third direction D3, without being limited thereto.

When the load port module 110 includes three load ports 110a, 110b, and 110c, the containers seated on each of the load ports 110a, 110b, and 110c may carry different types of items. For example, the first container seated on the first load port 110a may carry a substrate, the second container seated on the second load port 110b may carry a sensor, and the third container seated on the third load port 110c may carry a consumable component such as a focus ring. However, the containers seated on at least two of load ports 110a, 110b, and 110c may carry the same type of item, without being limited thereto.

The index module 120 may be provided as an interface for transporting the substrates between the load port module 110 and the cleaning module 130. The index module 120 may include a first module housing 121 and a first transport robot 122. The first module housing 121 may provide an internal environment as an atmospheric pressure environment. One or more first transport robot 122 may be provided inside the first module housing 121. The first transport robot 122 may move in the first direction D1 along a rail R. The first transport robot 122 may rotate clockwise or counterclockwise. The first transport robot 122 may carry in or carry out the substrate between the load port module 110 and the cleaning module 130.

The semiconductor fabricating equipment 100 may be provided to include an equipment front end module (EFEM). The equipment front end module may be configured to include the load port module 110 and the index module 120.

The cleaning module 130 may clean the substrate. The cleaning module 130 may be disposed between the index module 120 and the transfer module 140 as shown in FIG. 1. In some implementations, the cleaning module 130 may be disposed to be surrounded by the index module 120, the transfer module 140, and the substrate treating apparatus 200, as shown in FIG. 2. The cleaning module 130 may clean the substrates that require the polishing process and substrates for which the polishing process has been completed. The cleaning module 130 may clean only the substrates for which the polishing process has been completed but may not clean the substrates that require the polishing process. The cleaning module 130 may include a plurality of cleaning devices, but may include a single cleaning device, without being limited thereto.

In some implementations, each cleaning device may be configured to include a cleaning stage, a second platen, and a brush. The second platen and the brush may be disposed inside the cleaning stage. The substrate may be seated on the second platen. The second platen may support the substrate, while the substrate is being cleaned. The brush may be disposed in the upper portion of the second platen. The brush may move over the substrate to come into contact with the substrate and clean the substrate. The brush may clean foreign matters present on the substrate. The cleaning module 130 may use ultra-pure water (DIW) when cleaning the substrate.

The transfer module 140 may be provided as an interface for transporting the substrate between the cleaning module 130 and the substrate treating apparatus 200. The transfer module 140 may include a second module housing 141 and a second transfer robot 142. The second module housing 141 may provide its internal environment as an atmospheric pressure environment. One or more second transfer robots 142 may be provided inside the second module housing 141. The second transfer robot 142 may rotate clockwise or counterclockwise. The second transfer robot 142 may carry in or carry out the substrate between the cleaning module 130 and the substrate treating apparatus 200.

The substrate treating apparatus 200 may perform the polishing process for polishing the substrate. The substrate treating apparatus 200 may fabricate the substrate to a desired thickness through the polishing process. The substrate treating apparatus 200 may be provided as a grinding apparatus for flattening the surface of the substrate. For example, the substrate treating apparatus 200 may be provided as a chemical mechanical polishing (CMP) apparatus. A detailed description of the substrate treating apparatus 200 will be provided later.

The semiconductor fabricating equipment 100 may further include a buffer module 150. The buffer module 150 may temporarily store a substrate that requires the polishing process or a substrate for which the polishing process has been completed. The buffer module 150 may store a single substrate, but may store a plurality of substrates without being limited thereto. Referring to FIG. 2, the buffer module 150 may be disposed between the index module 120 and the substrate treating apparatus 200. The cleaning module 130, the transfer module 140, and the buffer module 150 may be aligned in the first direction D1. Each of the cleaning module 130 and the buffer module 150 may be disposed on both sides of the transfer module 140.

On the other hand, when the semiconductor fabricating equipment 100 includes the buffer module 150, the index module 120 may be provided as an interface for transporting the substrates between the load port module 110 and the buffer module 150. The transfer module 140 may be provided as an interface for transporting the substrate between the cleaning module 130 and the buffer module 150, or may be provided as an interface for transporting the substrate between the substrate treating apparatus 200 and the buffer module 150.

In some implementations, the semiconductor fabricating equipment 100 may further include a control device. The control device may control the overall operations of each module that constitutes the semiconductor fabricating equipment 100 and each unit included in each module. The control device may include a processor that executes the control for each unit that constitutes the semiconductor fabricating equipment 100, a network for wired and wireless communication with each unit, one or more instructions related to functions and operations for controlling each unit, a treating recipe including instructions, a storage means for storing various data, and the like. The control device may further include a user interface that includes an input means for performing command input operations and the like to manage the semiconductor fabricating equipment 100 by an operator, and an output means for visualizing and displaying the operating status of the semiconductor fabricating equipment 100. The control device may be provided as a computing device for data processing and analysis, instruction transmission, and the like.

The instructions may be provided in the form of a computer program or an application. The computer program may be stored in a computer-readable recording medium, including one or more instructions. The instructions may include code generated by a compiler, code that may be executed by an interpreter, or the like. The storage means may be provided as one or more storage media selected from a flash memory, an HDD, an SSD, a card-type memory, a RAM, an SRAM, a ROM, an EEPROM, a PROM, a magnetic memory, a magnetic disk, and an optical disk.

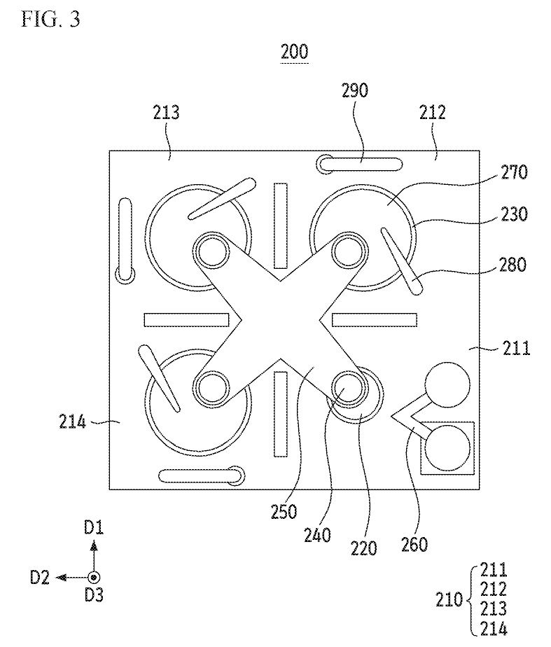

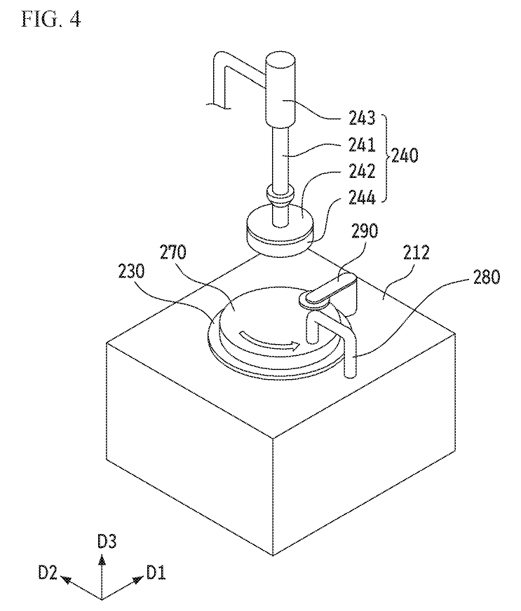

Next, the substrate treating apparatus 200 will be described. FIG. 3 is a plan view illustrating an internal structure of the substrate treating apparatus according to some implementations of the present disclosure. FIG. 4 is a perspective view illustrating the internal structure of the substrate treating apparatus according to some implementations of the present disclosure. Referring to FIGS. 3 and 4, the substrate treating apparatus 200 may include a base 210, a rod cup 220, a first platen 230, a spindle assembly 240, a support frame 250, an exchanger 260, a polishing pad 270, a slurry supply arm 280, and a pad conditioner 290.

The base 210 may be made up of four portions 211, 212, 213, and 214, such as a first portion 211, a second portion 212, a third portion 213, and a fourth portion 214. The four portions 211, 212, 213, and 214 may be disposed counterclockwise. The base 210 made up of the four portions 211, 212, 213, and 214 is merely an example. In some implementations, it can be understood that the base 210 can be made up of any number of portions.

The rod cup 220 and the exchanger 260 may be installed in the first portion 211. The transfer module 140 may transport a substrate that requires the polishing process to the substrate treating apparatus 200. When the substrate is carried into the first portion 211 inside the substrate treating apparatus 200, the exchanger 260 may transport the substrate to the load cup 220. The load cup 220 may temporarily store the substrate transported by the exchanger 260. The substrate may wait in the load cup 220. The substrate may then move onto the first platen 230 through the spindle assembly 240 connected to the support frame 250. As shown in the example of FIG. 3, a single portion 214 may be provided to support rod cup 220 and the exchanger 260, but multiple portions 214 may also be used, without being limited thereto.

The four components, including the first platen 230, the polishing pad 270, the slurry supply arm 280, and the pad conditioner 290, may be installed in each of the second portion 212, the third portion 213, and the fourth portion 214. As shown in the example of FIG. 3, there may be multiple portions, such as the portions 211, 212, and 213, in which the first platen 230, the polishing pad 270, the slurry supply arm 280, and the pad conditioner 290 are installed. In some implementations, a single portion may be provided, without being limited thereto. Hereinafter, although an example will be described in which the first platen 230, the polishing pad 270, the slurry supply arm 280, and the pad conditioner 290 are installed in the second portion 212, it will be understood that the first platen 230, the polishing pad 270, the pad slurry supply arm 280 and the pad conditioner 290 may be installed in the same manner in the third portion 213 and the fourth portion 214.

Referring to FIG. 4, the first platen 230 may engage the center portion of the second portion 212, and the polishing pad 270 may be disposed on the first platen 230. The second portion 212 may house a single first platen 230 and a single polishing pad 270, or multiple first platens 230 and polishing pads 270, without being limited thereto.

The first platen 230 may rotate clockwise or counterclockwise. In some implementations, the first platen 230 may be connected to a power source and a motor. The first platen 230 may rotate around a motor shaft. The motor may be built into the second portion 212. The power source may provide a driving force to the motor. The power source may be built into the second portion 212, but may be provided outside the substrate treating apparatus 200, without being limited thereto.

The polishing pad 270 may rotate by the rotational force of the first platen 230. The polishing pad 270 may rotate together with the first platen 230. The polishing pad 270 may rotate in the same direction as the first platen 230. The polishing pad 270 may be provided as a flat plate. The polishing pad 270 may include a roughened surface. The polishing pad 270 may mechanically polish the substrate when it comes into contact with the substrate through the rotational force and the rough surface.

A body of the slurry supply arm 280 may be disposed adjacent to the first platen 230. An end of the slurry supply arm 280 may be disposed on the polishing pad 270. The slurry supply arm 280 may provide the slurry to an upper face of the polishing pad 270. The slurry may include a reactant, abrasive particles, a chemical reaction catalyst, and the like. The reactant may include deionized water for oxidative polishing. The abrasive particles may include silicon dioxide for oxidative polishing. The chemical reaction catalyst may include potassium hydroxide for oxidative polishing.

The pad conditioner 290 may be disposed adjacent to the first platen 230. The pad conditioner 290 may be disposed adjacent to the slurry supply arm 280. The pad conditioner 290 may maintain the status of the polishing pad 270 so that the polishing efficiency for the substrate does not decrease.

Referring to FIG. 3, the support frame 250 may be configured with four arms. A spindle assembly 240 may be installed on each arm of the support frame 250. The spindle assembly 240 may be disposed on the four portions 211, 212, 213, and 214 of the base 210, respectively.

Referring again to FIG. 4, the spindle assembly 240 may include a spindle body 241, a grinding wheel 242, a drive unit 243, and a polishing head 244.

The spindle assembly 240 may adsorb or hold a substrate that is subjected to the polishing process. In this case, the polishing head 244 may adsorb the substrate so that the polishing surface of the substrate faces the polishing pad 270. However, the spindle assembly 240 may also grip the substrate to be subjected to the polishing process, without being limited thereto.

The drive unit 243 may provide power to move the spindle body 241 and the grinding wheel 242. The spindle body 241 and the grinding wheel 242 may move horizontally in the first direction D1 or the second direction D2. The spindle body 241 and the grinding wheel 242 may move vertically in the third direction D3. The spindle body 241 and the grinding wheel 242 may rotate clockwise or counterclockwise. In some implementations, only the grinding wheel 242 may rotate clockwise or counterclockwise.

The polishing head 244 may engage the grinding wheel 242. The polishing head 244 may perform a translational motion together with the grinding wheel 242 according to the horizontal movement and/or vertical movement of the grinding wheel 242. The polishing head 244 may perform a rotational motion together with the grinding wheel 242 according to the rotational movement of the grinding wheel 242. While the polishing process proceeds, the polishing head 244 may bring the substrate into contact with the polishing pad 270 while adsorbing the substrate. The polishing head 244 may press the substrate while bringing the substrate into close contact with the polishing pad 270. The drive unit 243 may control the three-dimensional positions (x, y, and z) of the spindle body 241, the grinding wheel 242, and the polishing head 244 to control the polishing portion of the substrate, the polishing degree for each portion of the substrate, or the like. Here, x may be defined as a position in the first direction D1, y may be defined as a position in the second direction D2, and z may be defined as a position in the third direction D3.

Referring to FIG. 3, multiple spindle assemblies 240 may be provided, with one spindle assembly corresponding to each portion of the base 210. In this case, the support frame 250 may include a plurality of arms, and each spindle assembly 240 may be connected to each arm of the support frame 250. The support frame 250 may rotate, and may move the spindle assembly 240 onto the polishing pad 270 or onto the rod cup 220 through the rotation. After loading the substrate from the load cup 220, the polishing head 244 holding the substrate may move onto the polishing pad 270, whereby the polishing pad 270 polishes the substrate. The polishing head 244 may unload the substrate onto the load cup 220 after the substrate polishing is completed. The exchanger 260 may move the substrate from the load cup 220 to the transfer module 140 after the polishing process is completed.

The substrate treating apparatus 200 may be provided as a grinding apparatus including the spindle assembly 240 for efficient polishing on the substrate and may use an air bearing. The substrate treating apparatus 200 may use a hydrostatic air bearing for stable high-speed rotation of the grinding wheel 242.

However, in the process of processing a substrate, the air bearing may become unstable due to various obstacles applied to the spindle body 241, such as void processing and edge tearing. The instability of the air bearing, caused by factors such as voids and chipping that may occur during substrate grinding, may result in a total thickness variation (TTV) and surface condition deterioration when processing the substrate.

The substrate treating apparatus 200 may stabilize the air bearing through an automatic stabilization device including an electronic pressure regulator. In addition, the substrate treating apparatus 200 may stabilize the air bearing through a stabilization algorithm. According to the present disclosure, it is possible to improve the performance of the substrate treating apparatus 200, shorten the preventive maintenance (PM) time, and reduce the PM cost through the stabilization of the air bearing. In addition, the performance deterioration of the substrate treating apparatus 200 can be detected early to improve the production yield and quality.

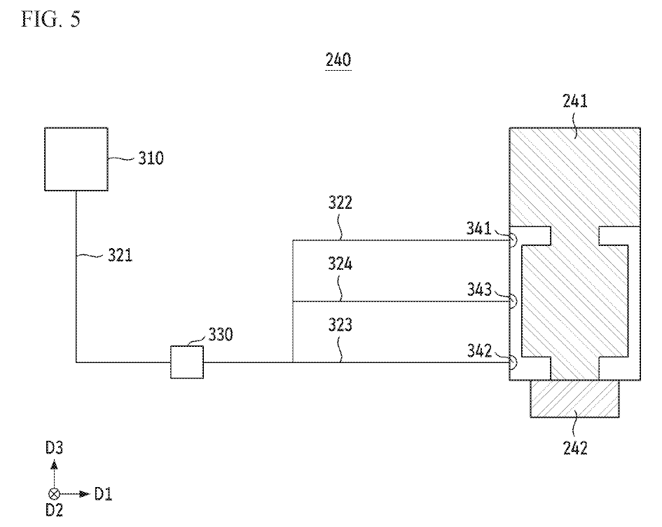

FIG. 5 is a first exemplary diagram illustrating the internal structure of a spindle assembly that constitutes the substrate treating apparatus according to some implementations of the present disclosure. Referring to FIG. 5, the spindle assembly 240 may be configured to include a spindle body 241, a grinding wheel 242, a fluid supply unit or fluid supplier 310, a first supply line 321, a second supply line 322, a third supply line 323, a fourth supply line 324, and a pressure controller 330. The spindle body 241 and the grinding wheel 242 may be defined as a spindle rotor together. The first supply line 321, the second supply line 322, the third supply line 323, and the fourth supply line 324 may be defined as a fluid supply line together.

In some implementations, the spindle assembly 240 may also include a drive unit 243 and a grinding head 244. The drive unit 243 may be connected to the spindle body 241. The drive unit 243 may cause the spindle body 241 and the grinding wheel 242 to move horizontally in the first direction D1 or the second direction D2. The drive unit 243 may cause the spindle body 241 and the grinding wheel 242 to move vertically in the third direction D3. The drive unit 243 may cause the spindle body 241 and the grinding wheel 242 to rotate clockwise or counterclockwise. The polishing head 244 may engage the grinding wheel 242. The polishing head 244 may bring the substrate into close contact with the polishing pad 270, rotate the substrate, and polish the substrate.

The fluid supply unit 310 may supply a fluid. The fluid supply unit 310 may supply a gas, but may also supply a liquid, without being limited thereto. The fluid supply unit 310 may be connected to the first supply line 321. The fluid supply unit 310 may supply a fluid to the first supply line 321.

The second supply line 322, the third supply line 323, and the fourth supply line 324 may be connected to the first supply line 321. The fluid may move from the first supply line 321 to the second supply line 322, the third supply line 323, and the fourth supply line 324. The second supply line 322, the third supply line 323, and the fourth supply line 324 may branch off from the first supply line 321. The second supply line 322, the third supply line 323, and the fourth supply line 324 may branch off from the same point, but may also branch off from different points, without being limited thereto.

The second supply line 322, the third supply line 323, and the fourth supply line 324 may be connected to the spindle body 241. The second supply line 322, the third supply line 323, and the fourth supply line 324 may be connected to different portions of the spindle body 241. The second supply line 322 may be connected to a first portion 341 of the spindle body 241. The third supply line 323 may be connected to a second portion 342 of the spindle body 241. The fourth supply line 324 may be connected to a third portion 343 of the spindle body 241.

The fluid may move to the first portion 341 of the spindle body 241 by passing through the first supply line 321 and the second supply line 322 in sequence. The fluid may move to the second portion 342 of the spindle body 241 by passing through the first supply line 321 and the third supply line 323 in sequence. The fluid may move to the third portion 343 of the spindle body 241 by passing through the first supply line 321 and the fourth supply line 324 in sequence. The fluid may move to each of the portions 341, 342, and 343 of the spindle body 241 through the second supply line 322, the third supply line 323, and the fourth supply line 324.

The first portion 341 may be located at a level higher than the second portion 342. The first portion 341 may be located at a level higher than the third portion 343. The third portion 343 may be located at a level higher than the second portion 342. The first portion 341 may be adjacent to the drive unit 243. The second portion 342 may be adjacent to the polishing head 244. For example, the first portion 341 may correspond to an upper portion of the spindle body 241, the second portion 342 may correspond to a lower portion of the spindle body 241, and the third portion 343 may correspond to an intermediate portion of the spindle body 241.

The pressure controller 330 may control the pressure provided to the spindle body 241 through the first supply line 321, the second supply line 322, the third supply line 323, and the fourth supply line 324. The pressure controller 330 may control the amount of fluid flowing to the spindle body 241 by controlling the pressure. The pressure controller 330 may measure the amount of fluid flowing through each of the supply lines 321, 322, 323, and 324 in real time, and adjust the amount of fluid passing through each of the supply lines 321, 322, 323, and 324 by controlling the pressure in real time according to a stabilization algorithm. The stabilization algorithm may be generated in advance and stored in the memory of the control device, but may also be generated on the basis of data obtained in the process of processing the substrate. A detailed description thereof will be given later.

The pressure controller 330 may control the pressure provided to the spindle body 241 in real time. The pressure controller 330 may variably control the pressure provided to the spindle body 241 in real time based on the amount of fluid flowing to the spindle body 241 during the substrate treating. The pressure controller 330 may automatically control the pressure provided to the spindle body 241. The pressure controller 330 may be provided as an electronic pressure regulator. If the pressure controller 330 is provided as a passive pressure regulator, stabilization of the air bearing requires halting equipment operation and stopping the air supply. In such a structure, because the residual pressure is removed from all pneumatic elements in the equipment, including the spindle assembly 240, the PM time may increase and may affect elements other than the spindle assembly 240. If the pressure controller 330 is provided as an electronic pressure regulator, the residual pressure is removed only in the spindle assembly 240, allowing air pressure to be stably applied to the air bearing, thereby enabling stable control of the spindle assembly 240.

The pressure controller 330 may form an air gap in the spindle body 241 through the fluid flowing to the spindle body 241. The pressure controller 330 may control the three-dimensional position of the polishing head 244 connected to the grinding wheel 242 through an air gap. The pressure controller 330 may control the polishing portion and the polishing degree of the substrate adsorbed to the polishing head 244. The pressure controller 330 may stabilize the air bearing.

The pressure controller 330 may uniformly control the amount of fluid provided to each of the portions 341, 342, and 343 of the spindle body 241. In this case, the pressure controller 330 may be installed in the first supply line 321. The pressure controller 330 may adjust the amount of fluid before branching into the second supply line 322, the third supply line 323, and the fourth supply line 324 such that the amount of fluid flowing to each of the supply lines 322, 323, and 324 becomes uniform. The pressure controller 330 can also be installed in each of the second supply line 322, the third supply line 323, and the fourth supply line 324.

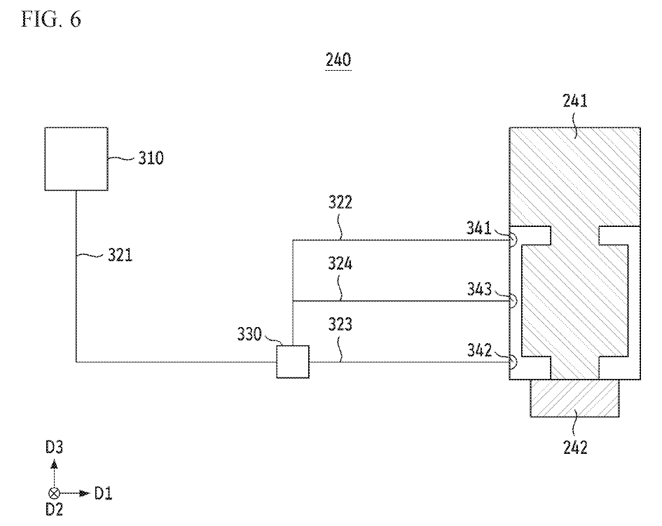

The pressure controller 330 may independently control the amount of fluid provided to each of the portions 341, 342, and 343 of the spindle body 241. Referring to FIG. 6, the pressure controller 330 may be installed at a branch point between the supply lines 321, 322, 323, and 324. The pressure controller 330 may equally control the amount of fluid flowing through the second supply line 322, the third supply line 323, and the fourth supply line 324. The pressure controller 330 may differently control the amount of fluid flowing through the second supply line 322, the third supply line 323, and the fourth supply line 324. The pressure controller 330 may equally control the amount of fluid flowing through some of the second supply line 322, the third supply line 323, and the fourth supply line 324, and may differently control the amount of fluid flowing through some other supply lines. FIG. 6 is a second exemplary diagram illustrating the internal structure of a spindle assembly that constitutes a substrate treating apparatus according to some implementations of the present disclosure.

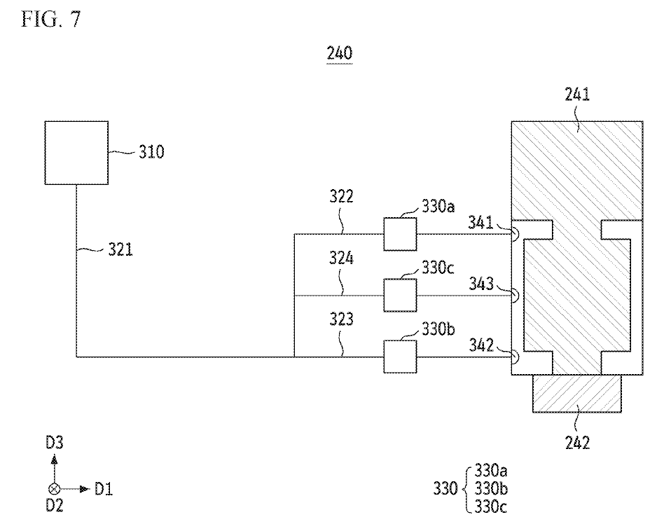

In some implementations, referring to FIG. 7, the pressure controller 330 may be installed in each of the second supply line 322, the third supply line 323, and the fourth supply line 324. The pressure controller 330 may include a first pressure control module 330a, a second pressure control module 330b, and a third pressure control module 330c. The first pressure control module 330a may be installed in the second supply line 322. The second pressure control module 330b may be installed in the third supply line 323. The third pressure control module 330c may be installed in the fourth supply line 324. The first pressure control module 330a, the second pressure control module 330b, and the third pressure control module 330c may equally control the amount of fluid. The first pressure control module 330a , the second pressure control module 330b, and the third pressure control module 330c may control the fluid amount differently. Some of the first pressure control module 330a, the second pressure control module 330b, and the third pressure control module 330c may control the fluid amount equally, while other pressure control modules may control the fluid amount differently. FIG. 7 is a third exemplary diagram illustrating the internal structure of a spindle assembly that constitutes a substrate treating apparatus according to some implementations of the present disclosure.

The pressure controller 330 may also control only the amount of fluid provided to a specific portion of the spindle body 241. In this case, the pressure controller 330 may control the amount of fluid provided to any one of the first portion 341, the second portion 342, and the third portion 343 of the spindle body 241. However, the pressure controller 330 may also control the amount of fluid provided to any two of the first portion 341, the second portion 342, and the third portion 343 of the spindle body 241, without being limited thereto.

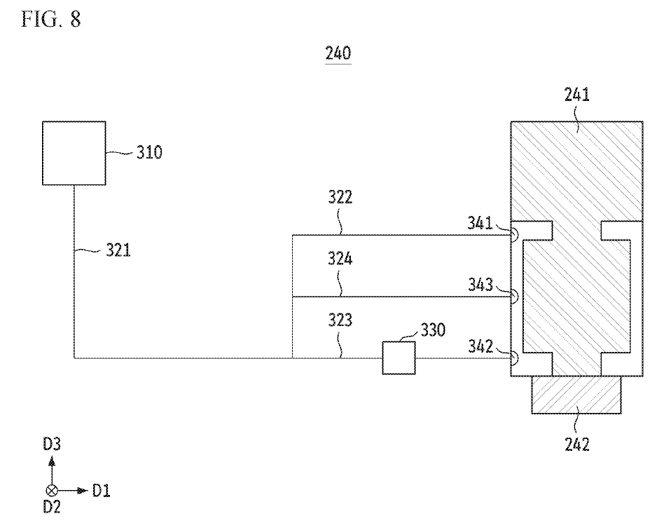

First, the former case will be described. FIG. 8 is a fourth exemplary diagram illustrating the internal structure of a spindle assembly that constitutes a substrate treating apparatus according to some implementations of the present disclosure. Referring to FIG. 8, the pressure controller 330 may be provided separately in the third supply line 323. The pressure controller 330 may independently control the amount of fluid provided to the second portion 342 of the spindle body 241. The pressure controller 330 may not control the amount of fluid provided to the first portion 341 and the third portion 343 of the spindle body 241.

In some implementations, the pressure controller 330 may be installed separately in the second supply line 322. The pressure controller 330 may independently control the amount of fluid provided to the first portion 341 of the spindle body 241. The pressure controller 330 may not control the amount of fluid provided to the second portion 342 and the third portion 343 of the spindle body 241.

In some implementations, the pressure controller 330 may be installed separately in the fourth supply line 324. The pressure controller 330 may independently control the amount of fluid provided to the third portion 343 of the spindle body 241. The pressure controller 330 may not control the amount of fluid provided to the first portion 341 and the second portion 342 of the spindle body 241.

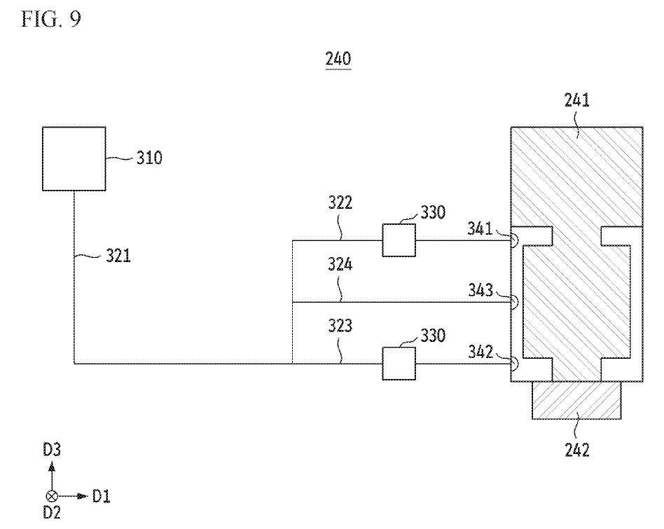

Next, the latter case will be described. FIG. 9 is a fifth exemplary diagram illustrating the internal structure of a spindle assembly that constitutes a substrate treating apparatus according to some implementations of the present disclosure. Referring to FIG. 9, the pressure controller 330 may be installed in the second supply line 322 and the third supply line 323. The pressure controller 330 may independently control the amount of fluid provided to the first portion 341 and the second portion 342 of the spindle body 241. The pressure controller 330 may equally control the amount of fluid provided to the two portions 341 and 342. The pressure controller 330 may differently control the amount of fluid provided to the two portions 341 and 342. The pressure controller 330 may not control the amount of fluid provided to the third portion 343 of the spindle body 241.

In some implementations, the pressure controller 330 may be installed in the second supply line 322 and the fourth supply line 324. The pressure controller 330 may independently control the amount of fluid provided to the first portion 341 and the third portion 343 of the spindle body 241. The pressure controller 330 may equally control the amount of fluid provided to the two portions 341 and 343. The pressure controller 330 may differently control the amount of fluid provided to the two portions 341 and 343. The pressure controller 330 may not control the amount of fluid provided to the second portion 342 of the spindle body 241.

In some implementations, the pressure controller 330 may be installed in the third supply line 323 and the fourth supply line 324. The pressure controller 330 may independently control the amount of fluid provided to the second portion 342 and the third portion 343 of the spindle body 241. The pressure controller 330 may equally control the amount of fluid provided to the two portions 342 and 343. The pressure controller 330 may differently control the amount of fluid provided to the two portions 342 and 343. The pressure controller 330 may not control the amount of fluid provided to the first portion 341 of the spindle body 241.

As described above, the pressure controller 330 may control the amount of fluid provided to a specific portion of the spindle body 241, and may not control the amount of fluid provided to other portions. However, it is also possible to control the amount of fluid provided to other portions using a flow meter, without being limited thereto.

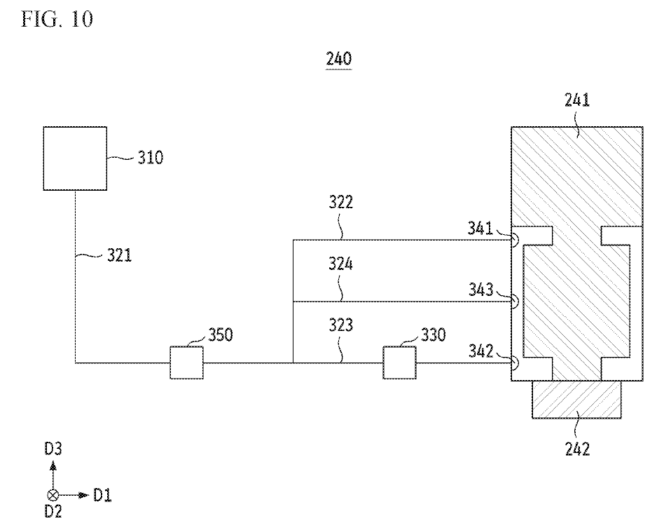

First, a case will be described in which the pressure controller 330 controls the amount of fluid provided to any one of the first portion 341, the second portion 342, and the third portion 343 of the spindle body 241. FIG. 10 is a sixth exemplary diagram illustrating the internal structure of a spindle assembly that constitutes a substrate treating apparatus according to some implementations of the present disclosure.

Referring to FIG. 10, the pressure controller 330 may be installed in the third supply line 323, and the flow meter 350 may be installed in the first supply line 321. The pressure controller 330 may be automatically operated, using a solenoid coil or the like. The pressure controller 330 may be provided as an electronic pressure regulator. The flow meter 350 may be manually operated using a lever, a button, or the like. The flow meter 350 may be provided as a passive pressure regulator.

The pressure controller 330 may independently control the amount of fluid provided to the second portion 342 of the spindle body 241. The flow meter 350 may uniformly control the amount of fluid provided to the first portion 341 and the third portion 343 of the spindle body 241. The amount of fluid provided to the second portion 342 may be different from the amount of fluid provided to the first portion 341 and the third portion 343, but may also be equal thereto, without being limited thereto.

In some implementations, the pressure controller 330 may be installed in the second supply line 322, and the flow meter 350 may be installed in the first supply line 321. The pressure controller 330 may independently control the amount of fluid provided to the first portion 341 of the spindle body 241. The flow meter 350 may uniformly control the amount of fluid provided to the second portion 342 and the third portion 343 of the spindle body 241. The amount of fluid provided to the first portion 341 may be different from the amount of fluid provided to the second portion 342 and the third portion 343, but may be equal thereto, without being limited thereto.

In some implementations, the pressure controller 330 may be installed in the fourth supply line 324 and the flow meter 350 may be installed in the first supply line 321. The pressure controller 330 may independently control the amount of fluid provided to the third portion 343 of the spindle body 241. The flow meter 350 may uniformly control the amount of fluid provided to the first portion 341 and the second portion 342 of the spindle body 241. The amount of fluid provided to the third portion 343 may be different from the amount of fluid provided to the first portion 341 and the second portion 342, but may be equal thereto, without being limited thereto.

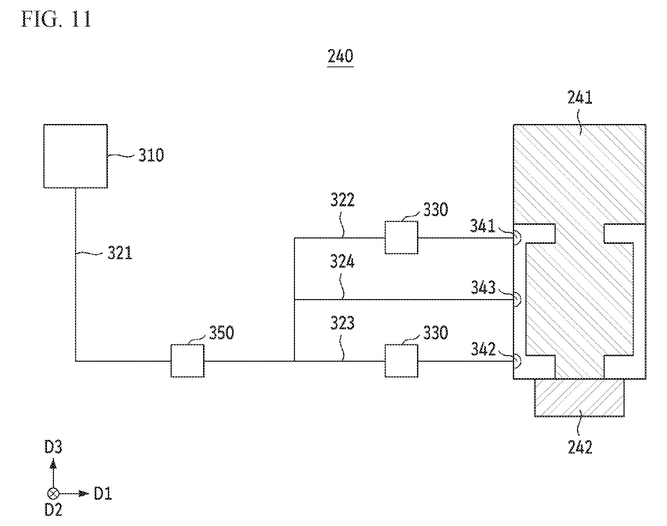

Next, a case where the pressure control portion 330 controls the amount of fluid provided to any two portions of the first portion 341, the second portion 342, and the third portion 343 of the spindle body 241 will be described. FIG. 11 is a seventh exemplary diagram illustrating an internal structure of a spindle assembly that constitutes a substrate treating apparatus according to some implementations of the present disclosure.

Referring to FIG. 11, the pressure control portion 330 may be installed in the second supply line 322 and the third supply line 323, and the flow meter 350 may be installed in the first supply line 321. The pressure control portion 330 may independently control the amount of fluid provided to the first portion 341 and the second portion 342 of the spindle body 241. The pressure controller 330 may equally control the amount of fluid provided to the first portion 341 and the second portion 342. The pressure controller 330 may differently control the amount of fluid provided to the first portion 341 and the second portion 342. The flow meter 350 may control the amount of fluid provided to the third portion 343 of the spindle body 241. The amount of fluid provided to the third portion 343 may be equal to at least one of the amount of fluid provided to the first portion 341 and the amount of fluid provided to the second portion 342, but may be different from both the amount of fluid provided to the first portion 341 and the amount of fluid provided to the second portion 342, without being limited thereto.

In some implementations, the pressure controller 330 may be installed in the second supply line 322 and the fourth supply line 324, and the flow meter 350 may be installed in the first supply line 321. The pressure controller 330 may independently control the amount of fluid provided to the first portion 341 and the third portion 343 of the spindle body 241. The pressure controller 330 may equally control the amount of fluid provided to the first portion 341 and the third portion 343. The pressure controller 330 may differently control the amount of fluid provided to the first portion 341 and the third portion 343. The flow meter 350 may control the amount of fluid provided to the second portion 342 of the spindle body 241. The amount of fluid provided to the second portion 342 may be equal to at least one of the amount of fluid provided to the first portion 341 and the amount of fluid provided to the third portion 343, but may also be different from both the amount of fluid provided to the first portion 341 and the amount of fluid provided to the third portion 343, without being limited thereto.

In some implementations, the pressure controller 330 may be installed in the third supply line 323 and the fourth supply line 324, and the flow meter 350 may be installed in the first supply line 321. The pressure controller 330 may independently control the amount of fluid provided to the second portion 342 and the third portion 343 of the spindle body 241. The pressure controller 330 may equally control the amount of fluid provided to the second portion 342 and the third portion 343. The pressure controller 330 may differently control the amount of fluid provided to the second portion 342 and the third portion 343. The flow meter 350 may control the amount of fluid provided to the first portion 341 of the spindle body 241. The amount of fluid provided to the first portion 341 may be equal to at least one of the amount of fluid provided to the second portion 342 and the amount of fluid provided to the third portion 343, but may also be different from both the amount of fluid provided to the second portion 342 and the amount of fluid provided to the third portion 343, without being limited thereto.

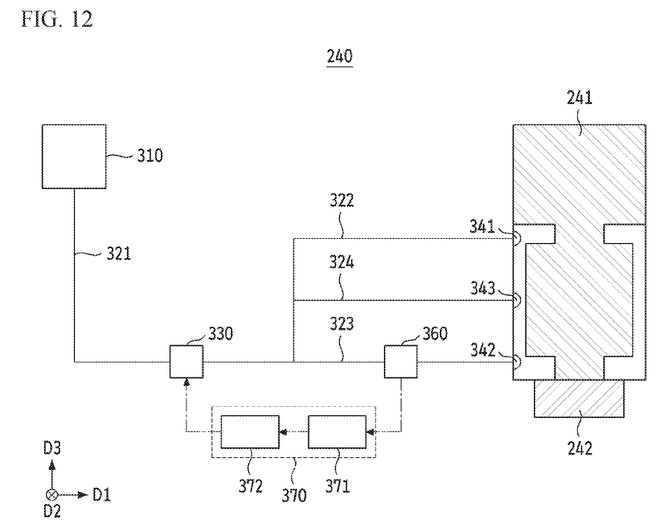

The substrate treating apparatus 200 may stabilize the air bearing through an electronic pressure regulator, but may also stabilize the air bearing through a stabilization algorithm, without being limited thereto. FIG. 12 is an eighth exemplary diagram illustrating an internal structure of a spindle assembly that constitutes a substrate treating apparatus according to some implementations of the present disclosure.

Referring to FIG. 12, the flow sensor 360 may be installed in the third supply line 323, and the pressure controller 330 may be installed in the first supply line 321. A stabilizer 370 may connect the flow sensor 360 and the pressure controller 330. The flow sensor 360 may measure the amount of fluid flowing to the second portion 242 of the spindle body 241. The stabilizer 370 may drive a stabilization algorithm on the basis of the result measured through the flow sensor 360. The pressure controller 330 may control the amount of fluid flowing to each of the portions 341, 342, and 343 of the spindle body 241 on the basis of the result calculated by the stabilization algorithm. The pressure controller 330 may uniformly control the amount of fluid flowing to each of the portions 341, 342, and 343 of the spindle body 241. The stabilizer 370 may include a signal processor 371 and an algorithm executor 372.

The signal processor 371 may perform signal processing on the measured result of the flow sensor 360. In a structure that uses an air bearing for stable high-speed rotation of the grinding wheel 242, the air gap of the spindle body 241 may be indirectly checked through the flow rate signal applied to the second portion 342 of the spindle body 241. The signal processor 371 may process the flow rate signal applied to the spindle body 241, thereby indirectly checking the stability of the air gap in the spindle body 241. A specific operating method of the signal processor 371 will be described later.

The algorithm executor 372 may operate a stabilization algorithm on the basis of the signal processing result of the signal processor 371. The signal processor 371 may calculate the dispersion of the flow rate through flow rate signal processing. For example, the signal processor 371 may calculate the dispersion of the flow rate, using a standard deviation or the like. The algorithm executor 372 may determine the stability of the air bearing, using the dispersion magnitude of the flow rate collected during the substrate processing. The algorithm executor 372 may determine the stability of the air bearing under various process conditions, using the dispersion magnitude of the flow rate calculated by the flow rate signal processing. The algorithm executor 372 may determine the stability of the air bearing under high-speed rotation conditions, but may also determine the stability of the air bearing under medium-speed rotation conditions and low-speed rotation conditions, without being limited thereto. If the dispersion magnitude of the flow rate is within the normal range, the algorithm executor 372 may determine that the next substrate processing may be performed. A specific operating method of the algorithm executor 372 will be described later.

In some implementations, the flow sensor 360 may be provided on either the second supply line 322 or the fourth supply line 324. The pressure controller 330 may uniformly control the amount of fluid flowing to each of the portions 341, 342, and 343 of the spindle body 241 on the basis of the amount of fluid flowing through any of the supply lines.

In some implementations, the flow sensor 360 may be installed on a plurality of supply lines selected from the second supply line 322 to the fourth supply line 324. The pressure controller 330 may uniformly control the amount of fluid flowing to each of the portions 341, 342, and 343 of the spindle body 241 on the basis of the amount of fluid flowing through any one supply line selected according to the weight among the plurality of supply lines. In some implementations, the pressure controller 330 may uniformly control the amount of fluid flowing to each of the portions 341, 342, and 343 of the spindle body 241 on the basis of a value (ex., an average value) obtained by calculating the amounts of fluid flowing through each supply line.

In some implementations, the pressure controller 330 may be installed at a branch point connecting the first supply line 321, the second supply line 322, the third supply line 323, and the fourth supply line 324 to independently control the amount of fluid flowing to each of the portions 341, 342, and 343 of the spindle body 241. In some implementations, the pressure controller 330 can be installed in each of the second supply line 322 to the fourth supply line 324.

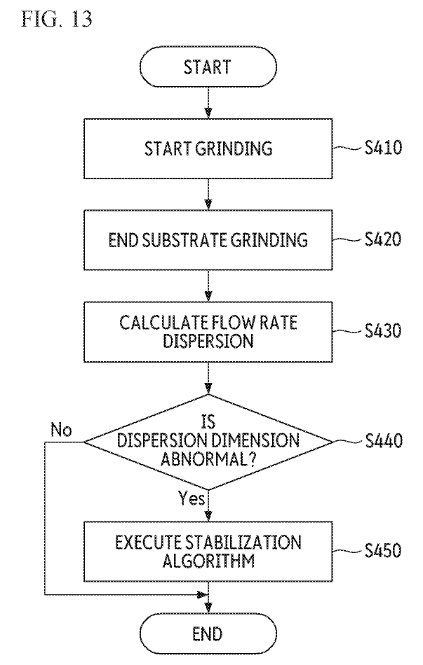

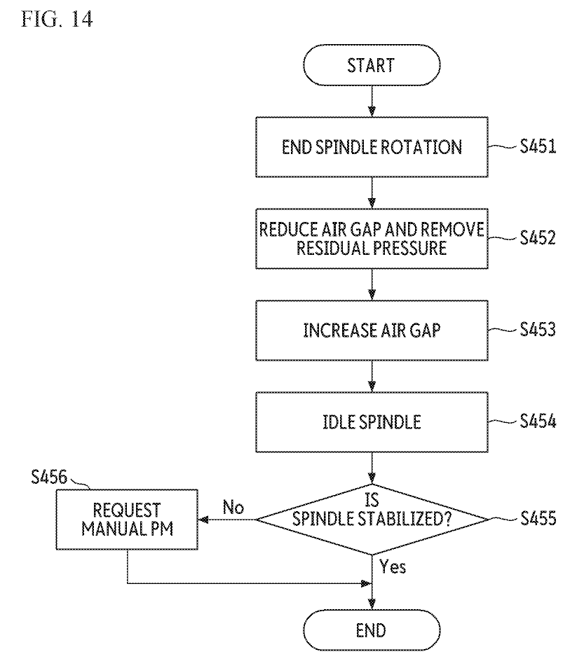

Next, the operating method of the signal processor 371 and the operating method of the algorithm executor 372 will be described in order. FIG. 13 is a first exemplary diagram illustrating a stabilizer in a spindle assembly that constitutes a substrate treating apparatus according to some implementations of the present disclosure. FIG. 14 is a second exemplary diagram illustrating a stabilizer in a spindle assembly that constitutes a substrate treating apparatus according to some implementations of the present disclosure. First, the operating method of the signal processor 371 will be described referring to FIG. 13, and then the operating method of the algorithm executor 372 will be described referring to FIG. 14.

Referring to FIG. 13, when grinding for processing the substrate is started (S410), the substrate may be thinned through a grinding step performed via three steps. Here, the grinding step may include a rough grinding step, a fine grinding step, and an ultra-fine grinding step, as each step. The spindle assembly 240 may be configured as an independent product for each step. For example, the spindle assembly 240 that performs the rough grinding step may be connected to one arm of the support frame 250. The spindle assembly 240 that performs the rough grinding step may perform the polishing process at the second portion 212 of the base 210. The spindle assembly 240 that performs the fine grinding step may be connected to the other arm of the support frame 250. The spindle assembly 240 that performs the fine grinding step may perform the polishing process at the third portion 213 of the base 210. The spindle assembly 240 that performs the ultra-fine grinding step may be connected to another arm of the support frame 250. The spindle assembly 240 that performs the ultra-fine grinding step may perform the polishing process at the fourth portion 214 of the base 210.

When the grinding step performed via three steps is completed (S420), the signal processor 371 may calculate the dispersion of the flow rate using the flow meter signal data collected in the procedure of processing the substrate (S430). The signal processor 371 may calculate the standard deviation, IQR (Inter-Quartile Range), deviation, range, and the like as the dispersion of the flow rate.

The signal processor 371 may determine whether the dispersion magnitude of the flow rate is in a normal state or an abnormal state (S440). Here, the normal state means a case where the dispersion magnitude of the flow rate matches a reference range, and the abnormal state means a case where the dispersion magnitude of the flow rate is outside the reference range. If the dispersion magnitude of the flow rate is determined to be in an abnormal state, the signal processor 371 may request the execution of a stabilization algorithm (S450). If the dispersion magnitude of the flow rate is determined to be in a normal state, the signal processor 371 may not request the execution of a stabilization algorithm.

When the execution of the stabilization algorithm is requested (S450), the algorithm executor 372 may stabilize the air bearing of the spindle body 241 in cooperation with the pressure controller 330. Referring to FIG. 14, the algorithm executor 372 may stop the rotation of the spindle body 241 and the grinding wheel 242 that are rotating (S451). After that, the algorithm executor 372 may decrease the air gap of the spindle body 241 through the pressure controller 330 (S452), and then increase the air gap of the spindle body 241 (S453).

When decreasing the air gap of the spindle body 241, the pressure controller 330 may decrease the pressure inside the spindle body 241 according to a first slope rate and remove a residual pressure (S452). Next, when increasing the air gap of the spindle body 241, the pressure controller 330 may increase the pressure inside the spindle body 241 up to a set value according to a second slope rate (S453). The second slope rate may be provided at a slope angle that is equivalent to the first slope rate. The pressure controller 330 may increase the pressure inside the spindle body 241 at a rate equivalent to that of decreasing the pressure inside the spindle body 241.

After that, the spindle body 241 and the grinding wheel 242 are idled (S454). The spindle body 241 and the grinding wheel 242 may be rotated at a speed that is equivalent to a case where processing the substrate. The spindle body 241 and the grinding wheel 242 may be rotated in a state in which no substrate is provided.

After that, the algorithm executor 372 determines whether the air bearing is stable through the flow rate condition (S455). If the flow rate condition satisfies the reference condition, the algorithm executor 372 may terminate the stabilization algorithm by considering the air bearing to be stabilized. On the other hand, if the flow rate condition does not satisfy the reference condition, the algorithm executor 372 considers that the air bearing cannot be stabilized due to another issue, and may request manual preventive maintenance (PM) to an administrator terminal (S456).

In some implementations, if the flow rate condition does not satisfy the reference condition, the algorithm executor 372 is also able to change the control method of the pressure controller 330 and execute again from step S452.

When the air gap of the spindle body 241 is reduced, the pressure controller 330 may reduce the pressure inside the spindle body 241 according to the third slope rate and remove the residual pressure (S452). The third slope rate may be provided at a slope angle different from the first slope rate. The third slope rate may have a gentler slope angle than the first slope rate. The pressure controller 330 may reduce the pressure inside the spindle body 241 at a slower speed than before and remove the residual pressure.

Subsequently, when the air gap of the spindle body 241 is increased, the pressure controller 330 may increase the pressure inside the spindle body 241 up to a set value according to a fourth slope rate (S453). The fourth slope rate may be provided at a slope angle that is equivalent to the third slope rate. The pressure controller 330 may increase the pressure inside the spindle body 241 at a rate equivalent to that of decreasing the pressure inside the spindle body 241.

If the flow rate condition does not yet satisfy the reference condition, the process may be repeated from step S452. The pressure controller 330 may reduce the pressure inside the spindle body 241 according to a fifth slope rate and remove the residual pressure. The fifth slope rate may have a gentler slope angle than the third slope rate. The pressure controller 330 may reduce the pressure inside the spindle body 241 at a slower speed than before and remove the residual pressure. However, the pressure controller 330 may also reduce the pressure inside the spindle body 241 again according to the third slope rate and remove the residual pressure, without being limited thereto. The pressure controller 330 may reduce the pressure inside the spindle body 241 at the same speed as before, and remove the residual pressure.

When the air gap of the spindle body 241 is increased, the pressure controller 330 may increase the pressure inside the spindle body 241 up to a set value according to the sixth slope rate. The sixth slope rate may have a gentler slope angle than the fourth slope rate. The pressure controller 330 may increase the pressure inside the spindle body 241 up to a set value at a slower speed than before. However, the pressure controller 330 may increase the pressure inside the spindle body 241 up to a set value according to the fourth slope rate, without being limited thereto. The pressure controller 330 may increase the pressure inside the spindle body 241 at the same rate as before.

If the flow rate condition does not satisfy the reference condition, the process of repeating steps S452 to S455 may be performed N times. Here, N may be a natural number equal to or greater than 2. If the flow rate condition does not satisfy the reference condition despite steps S452 to S455 being repeated N times, the algorithm executor 372 may execute step S456.

The spindle assembly 240 may move the fluid to the first portion 341, the second portion 342, and the third portion 343 of the spindle body 241 through the second supply line 322, the third supply line 323, and the fourth supply line 324. The first portion 341, the second portion 342, and the third portion 343 may be formed in an upper region, a lower region, and a middle region of the spindle body 241, respectively. The fluid may move to the entire region of the spindle body 241. The fluid may be radially ejected from the third portion 343 of the spindle body 241. The fluid may be ejected from the third portion 343 in the first direction D1. However, the fluid may also be ejected from the third portion 343 in the third direction D3 without being limited thereto. Meanwhile, the fluid may also be ejected radially from the first portion 341 or the second portion 342 of the spindle body 241.

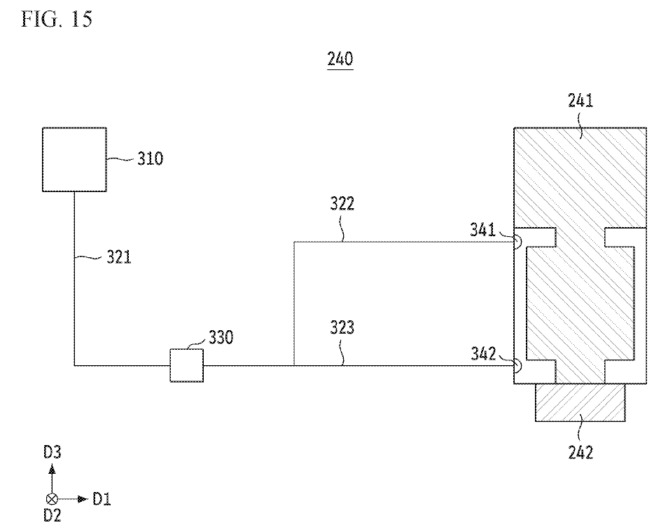

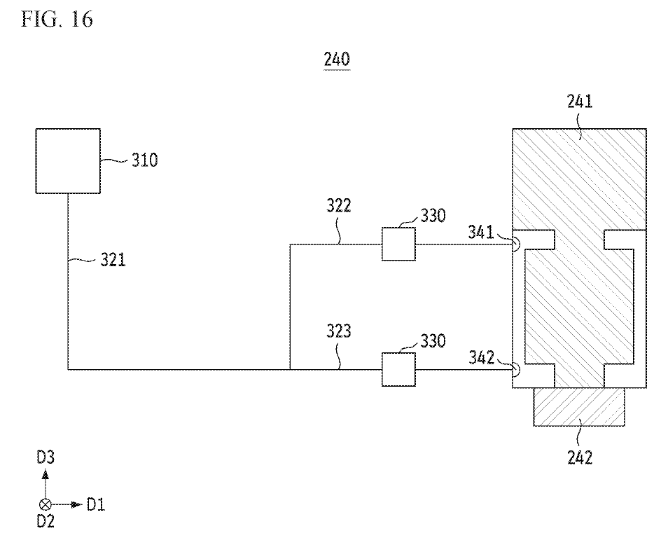

The fluid may move to each of the upper region, the middle region, and the lower region of the spindle body 241, but may also move to each of the upper region and the lower region of the spindle body 241, without being limited thereto. FIG. 15 is a ninth exemplary diagram illustrating an internal structure of a spindle assembly that constitutes the substrate treating apparatus according to some implementations of the present disclosure. FIG. 16 is a tenth exemplary diagram illustrating an internal structure of a spindle assembly that constitutes the substrate treating apparatus according to some implementations of the present disclosure.

Referring to FIG. 15, a pressure controller 330 may be installed in the first supply line 321. The pressure controller 330 may uniformly control the amount of fluid flowing to the first portion 341 and the second portion 342 of the spindle body 241 through the second supply line 322 and the third supply line 323.

In some implementations, a flow sensor 360 may be installed in at least one of the second supply line 322 and the third supply line 323, and the stabilizer 370 may connect the flow sensor 360 and the pressure controller 330. The pressure controller 330 may control the amount of fluid flowing to the first portion 341 and the second portion 342 of the spindle body 241 on the basis of the stabilization algorithm of the stabilizer 370.

Referring to FIG. 16, the pressure controller 330 may be installed in each of the second supply line 322 and the third supply line 323. The pressure controller 330 may independently control the amount of fluid flowing to the first portion 341 and the second portion 342 of the spindle body 241. In some implementations, the pressure controller 330 may be provided at a branch point connecting the first supply line 321, the second supply line 322, and the third supply line 323, without being limited thereto.

In some implementations, the flow sensor 360 may be installed in either the second supply line 322 or the third supply line 323. When the flow sensor 360 is installed in the second supply line 322, it may be installed between the first portion 341 of the spindle body 241 and the pressure controller 330. When the flow sensor 360 is installed in the third supply line 323, it may be installed between the second portion 342 of the spindle body 241 and the pressure controller 330. The stabilizer 370 may connect the flow sensor 360 and the pressure controller 330. The pressure controller 330 installed in the second supply line 322 may independently control the amount of fluid flowing to the first portion 341 of the spindle body 241 on the basis of a stabilization algorithm. The pressure controller 330 installed in the third supply line 323 may independently control the amount of fluid flowing to the second portion 342 of the spindle body 241 on the basis of a stabilization algorithm.

In some implementations, the flow sensor 360 may be installed in each of the second supply line 322 and the third supply line 323. The pressure controller 330 installed in the second supply line 322 may independently control the amount of fluid flowing to the first portion 341 of the spindle body 241, using the flow sensor 360 installed in the second supply line 322. The pressure controller 330 installed in the third supply line 323 may independently control the amount of fluid flowing to the second portion 342 of the spindle body 241, using the flow sensor 360 installed in the third supply line 323.

The fluid may move to the entire region of the spindle body 241, but may also move to only a partial region of the spindle body 241, without being limited thereto. When the spindle body 241 is divided into three regions, such as an upper region, a middle region, and a lower region, the fluid may move to two regions of the spindle body 241. As described referring to FIGS. 15 and 16, the fluid may move to the upper region and the lower region of the spindle body 241. However, the fluid may move only to one region of the spindle body 241, without being limited thereto.

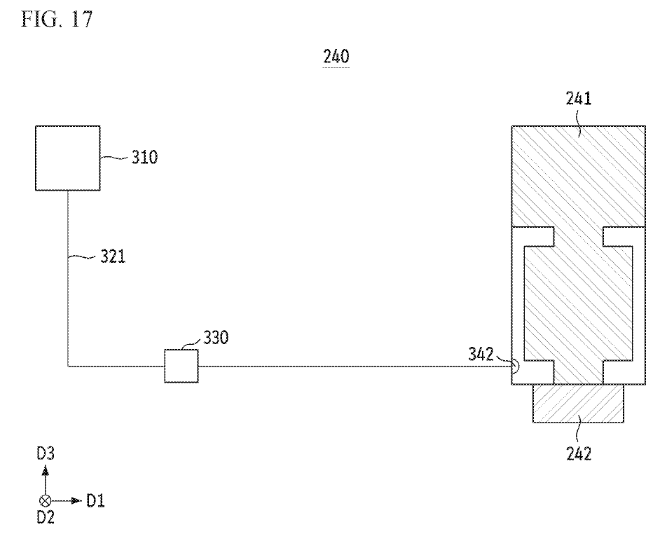

Referring to FIG. 17, the fluid may move to the lower region of the spindle body 241. The pressure controller 330 may control the amount of fluid flowing to the second portion 342 of the spindle body 241. In some implementations, the flow sensor 360 may be installed between the second portion 342 of the spindle body 241 and the pressure controller 330. The stabilizer 370 may connect the flow sensor 360 and the pressure controller 330. The pressure controller 330 may control the amount of fluid flowing to the second portion 342 of the spindle body 241 on the basis of the measured result of the flow sensor 360. FIG. 17 is an eleventh exemplary diagram illustrating an internal structure of a spindle assembly that constitutes the substrate treating apparatus according to some implementations of the present disclosure.

The substrate treating apparatus 200 may cut or polish a substrate through the rotation of the spindle assembly 240. The substrate treating apparatus 200 may be provided as a grinder or CMP equipment. The substrate treating apparatus 200 may minimize the frictional force of the high-speed rotating body, using an air bearing.

However, an axial runout may occur due to installation error or eccentricity of the grinding wheel 242 installed on the air bearing, and dynamic axial runout performance may be further deteriorated under processing conditions such as a high number of rotations. If the substrate treating apparatus 200 includes the pressure controller 330 installed as the electronic pressure regulator, the stability of the air bearing of the spindle assembly 240 can be monitored in real time, and the presence or absence of deterioration of the process result can be indirectly monitored.

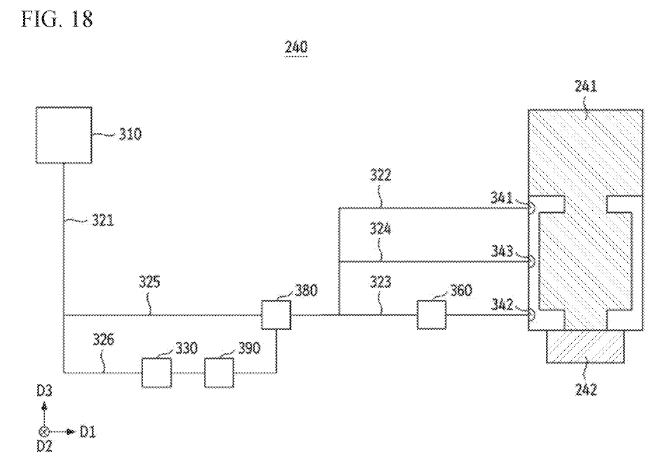

However, because a structure using only the electronic pressure regulator is an electronic control device, active control is possible, but if it becomes unstable, the air bearing may be damaged. The substrate treating apparatus 200 may be configured to select an active path or a passive path through a path switch valve. FIG. 18 is a twelfth exemplary diagram illustrating an internal structure of a spindle assembly that constitutes the substrate treating apparatus according to some implementations of the present disclosure.

Referring to FIG. 18, the first supply line 321 may branch into a fifth supply line 325 and a sixth supply line 326. The fifth supply line 325 may branch into a second supply line 322, a third supply line 323, and a fourth supply line 324. The second supply line 322 may be connected to the first portion 341 of the spindle body 241. The third supply line 323 may be connected to the second portion 342 of the spindle body 241. The fourth supply line 324 may be connected to the third portion 343 of the spindle body 241. The sixth supply line 326 may engage the fifth supply line 325 before the fifth supply line 325 branches into the second supply line 322, the third supply line 323, and the fourth supply line 324.

The flow sensor 360 may be installed in the third supply line 323. In some implementations, the flow sensor 360 may be installed in the second supply line 322 or the fourth supply line 324, without being limited thereto. In some implementations, the flow sensor 360 may be installed in one or more of the supply lines from the second supply line 322 to the fourth supply line 324. In some implementations, the spindle assembly 240 may not include all of the second supply line 322 to the fourth supply line 324, but may include any one or any two of the second supply line 322 to the fourth supply line 324.

A path switch valve 380 may be installed in the fifth supply line 325. The fifth supply line 325 may be provided as a passive path. The pressure controller 330 and the flow controller 390 may be installed in the sixth supply line 326. The sixth supply line 326 may be provided as an active path. The sixth supply line 326 may be connected to the path switch valve 380. The path switch valve 380 may select either the passive path or the active path. When the passive path is selected, the pressure controller 330 may not control the amount of fluid flowing to each of the portions 341, 342, and 343 of the spindle body 241. When the passive path is selected, the stability of the air bearing for the spindle assembly 240 may be maintained according to conventional methods. When the active path is selected, the pressure controller 330 may control the amount of fluid flowing to each of the portions 341, 342, and 343 of the spindle body 241. When the active path is selected, the stability of the air bearing for the spindle assembly 240 may be maintained according to the method of the present disclosure.

The pressure controller 330 may directly control the pressure provided to each of the portions 341, 342, and 343 of the spindle body 241. The flow controller 390 may directly control the amount of fluid flowing to each of the portions 341, 342, and 343 of the spindle body 241. The pressure controller 330 may indirectly control the amount of fluid flowing to each of the portions 341, 342, and 343 of the spindle body 241 by controlling the pressure provided to each of the portions 341, 342, and 343 of the spindle body 241. The sixth supply line 326 may also include either the pressure controller 330 or the flow controller 390.

The pressure controller 330 may be provided as an electronic pressure regulator. The flow controller 390 may be provided as an electronic flow regulator. When each of the pressure controller 330 and the flow controller 390 is installed in the sixth supply line 326, the pressure supplied to the air bearing as well as the flow rate may be controlled simultaneously. In a spindle structure such as a grinder equipment, the air bearing supports the grinding wheel 242 and the wheel flange, making it difficult to quantify the height of the air gap, as the air gap varies with the weight and installation error. When the spindle assembly 240 includes both the pressure controller 330 and the flow controller 390, it is possible to adjust the pressure and flow rate simultaneously to maintain stiffness (pressure) and adjust the flow rate for each spindle to set and control the height of the grinding wheels 242 to be equal.

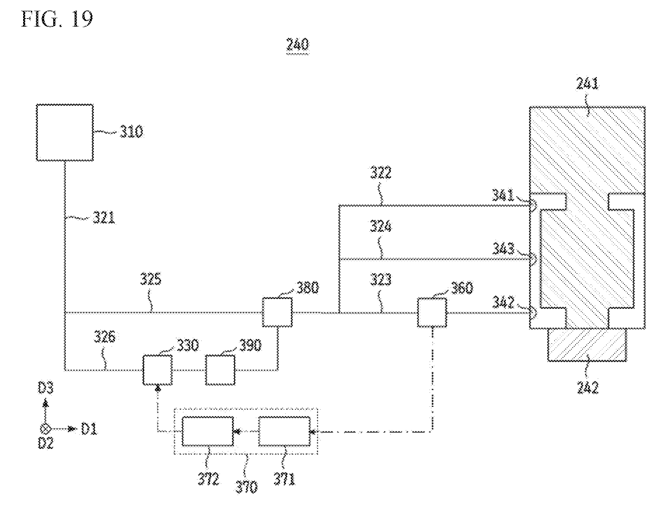

The spindle assembly 240 may include the stabilizer 370 for controlling pressure provided to each of the portions 341, 342, and 343 of the spindle body 241 through the stabilizing algorithm. FIG. 19 is a thirteenth exemplary diagram illustrating an internal structure of the spindle assembly that constitutes the substrate treating apparatus according to some implementations of the present disclosure. Referring to FIG. 19, the stabilizer 370 may connect the flow sensor 360 and the pressure controller 330. Not only the sixth supply line 326 provided with the pressure controller 330 and the flow controller 390, but also the line provided with the stabilizer 370 may be provided as active paths.

Although implementations of the present disclosure have been described with reference to the accompanying drawings, the present disclosure is not limited to the above implementations, but may be implemented in various different forms. A person skilled in the art may appreciate that the present disclosure may be practiced in other concrete forms without changing the technical concept or characteristics of the present disclosure. Therefore, it may be appreciated that the implementations as described above are not restrictive but illustrative in all respects.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A substrate treating apparatus comprising:
a base;
a polishing pad on the base and configured to polish a substrate;
a slurry supply arm adjacent to the polishing pad and configured to supply a slurry; and
a spindle assembly over the polishing pad and configured to polish the substrate using the polishing pad,
wherein the spindle assembly includes:
a polishing head configured to hold the substrate;
a spindle rotor configured to rotate the polishing head;
a fluid supplier configured to supply a fluid;
a fluid supply line configured to connect the fluid supplier to the spindle rotor; and
a pressure controller installed on the fluid supply line and configured to electrically control a pressure supplied to the spindle rotor.

2. The substrate treating apparatus of claim 1, wherein the fluid supply line includes:
a first supply line connected to the fluid supplier;
a second supply line connecting the first supply line to a first portion of the spindle rotor;
a third supply line connecting the first supply line to a second portion of the spindle rotor; and
a fourth supply line connecting the first supply line to a third portion of the spindle rotor.

3. The substrate treating apparatus of claim 2,
wherein the pressure controller is installed on the first supply line.

4. The substrate treating apparatus of claim 3,
wherein the pressure controller is configured to provide a uniform pressure to the first portion, the second portion, or the third portion.

5. The substrate treating apparatus of claim 2,
wherein the pressure controller is installed on one or more of the second supply line, the third supply line, or the fourth supply line.

6. The substrate treating apparatus of claim 5,
wherein the pressure controller is configured to independently control a pressure provided to the one or more of the first portion, the second portion, or the third portion.

7. The substrate treating apparatus of claim 2,
wherein the pressure controller is configured to independently control one or more of the first portion, the second portion, or the third portion.

8. The substrate treating apparatus of claim 7,
wherein the spindle assembly includes a flow meter configured to control a flow rate of the fluid provided to one or more portions that are not independently controlled by the pressure controller.

9. The substrate treating apparatus of claim 8,
wherein the flow meter is installed in the first supply line.

10. The substrate treating apparatus of claim 2, wherein the first supply line includes:
a fifth supply line;
a sixth supply line; and
a path switch valve connected to the fifth supply line and the sixth supply line, and configured to select one of the fifth supply line and the sixth supply line as a movement path of the fluid.

11. The substrate treating apparatus of claim 10,
wherein the pressure controller is installed in the sixth supply line.

12. The substrate treating apparatus of claim 11,
wherein the spindle assembly includes a flow controller installed in the sixth supply line, and configured to control a flow rate of the fluid provided to one or more of the first portion, the second portion, or the third portion.

13. The substrate treating apparatus of claim 12,
wherein the flow controller is installed between the pressure controller and the path switch valve.

14. The substrate treating apparatus of claim 2, wherein the spindle assembly includes:
a flow sensor configured to measure a flow rate in the fluid supply line; and
a stabilizer configured to determine a pressure supplied to the spindle rotor based on a measured result of the flow sensor.

15. The substrate treating apparatus of claim 14,
wherein the flow sensor is installed in at least one of the second supply line, the third supply line, or the fourth supply line.

16. The substrate treating apparatus of claim 14,
wherein the pressure controller is configured to variably control the pressure supplied to the spindle rotor in real time.

17. The substrate treating apparatus of claim 14, wherein the stabilizer includes:
a signal processor configured to process signal data related to the flow rate; and
an algorithm executor configured to calculate a dispersion of the flow rate based on a processing result of the signal data, and determine a stability of an air bearing provided on the spindle rotor based on the dispersion of the flow rate.

18. The substrate treating apparatus of claim 14, wherein the first supply line includes:
a fifth supply line;
a sixth supply line; and
a path switch valve connected to the fifth supply line and the sixth supply line, and configured to select one of the fifth supply line and the sixth supply line as a movement path of the fluid, and
wherein the pressure controller is installed on the sixth supply line.

19. A substrate treating apparatus comprising:
a base;
a polishing pad on the base and configured to polish a substrate;
a slurry supply arm adjacent to the polishing pad and configured to supply a slurry; and
a spindle assembly over the polishing pad and configured to polish the substrate using the polishing pad,
wherein the spindle assembly includes:
a polishing head configured to hold the substrate;
a spindle rotor configured to rotate the polishing head;
a fluid supplier configured to supply a fluid;
a fluid supply line configured to connect the fluid supplier to the spindle rotor; and
a pressure controller installed on the fluid supply line and configured to electrically control a pressure supplied to the spindle rotor,
wherein the fluid supply line includes:
a first supply line connected to the fluid supplier;
a second supply line connecting the first supply line to a first portion of the spindle rotor;
a third supply line connecting the first supply line to a second portion of the spindle rotor; and
a fourth supply line connecting the first supply line to a third portion of the spindle rotor, and
wherein the third supply line is disposed at a level lower than the second supply line and the fourth supply line, and
wherein the pressure controller is configured to independently control the pressure provided through the second portion.

20. A substrate treating apparatus comprising:
a base;
a polishing pad on the base and configured to polish a substrate;
a slurry supply arm adjacent to the polishing pad and configured to supply a slurry; and
a spindle assembly over the polishing pad and configured to polish the substrate using the polishing pad,
wherein the spindle assembly includes:
a polishing head configured to hold the substrate;
a spindle rotor configured to rotate the polishing head;
a fluid supplier configured to supply a fluid;
a fluid supply line configured to connect the fluid supplier to the spindle rotor; and
a pressure controller installed on the fluid supply line and configured to variably control a pressure supplied to the spindle rotor.
